(19) United States
(12) Patent Application Publication
(10) Pub. No.: US 2015/0319874 A1
(43) Pub. Date: Nov. 5, 2015

(54) FOLDABLE COVER

(71) Applicants: Igor DUC, (US); John BRUNNER, (US)

(72) Inventors: Igor DUC, Sheung Wan (HK); John BRUNNER, Sheung Wan (HK)

(73) Assignee: Design Pool Limited, Hong Kong (CN)

(21) Appl. No.: 14/651,263

(22) PCT Filed: Dec. 28, 2012
(86) PCT No.: PCT/CN2012/087788

§ 371 Date: Jun. 11, 2015

(51) Int. Cl. H05K 5/03; H05K 5/02; H05K 5/00

(52) U.S. Cl. CPC H05K 5/03; H05K 5/0086; H05K 5/0226; H05K 5/023; H05K 5/0239; A47B 2220/0091

(57) ABSTRACT

A foldable cover includes a hinge suitable for detachable attachment to a host unit and a flap portion. The flap portion is pivotally connected to the hinge and includes a plurality of segments which are substantially the same size and substantially rigid, with a foldable region between each of them. The flap portion is capable of being folded into a rectangular structure in which each segment of the flap portion is folded substantially flush one atop the other. The size and positioning of the resultant rectangular structure is such that the back face of the host unit can be further augmented to improve its utility or ergonomics, for example by the addition of a handle.

### TECHNICAL FIELD

The invention relates to covers for portable electronic devices, more particularly segmented folding covers.

### BACKGROUND OF THE INVENTION

Modern handheld electronic devices, for example mobile telephones and tablet computers, conventionally have a front-facing display on which information is presented to a user. Interchangeable covers are popular accessories for such devices. Such covers may be of a basic type having a housing into which the electronic device may be inserted. Commonly, the housing is moulded to accommodate the electronic device. The electronic device is thus afforded some protection from shocks such as being dropped.

Some housings may include an adjustable stand capable of being manipulated so as to provide support for the electronic device such that it may rest on a surface with the display screen at a comfortable reading and/or input angle. It is readily apparent that the stand could be designed to also function as a carrying handle for the device, as seen for example in international publication WO 2009/153494. These features are desirable as handheld electronic devices can be relatively heavy and an operator can become fatigued from holding them, particularly when a constant gripping force is required. If a stand is included it is common practice to allow it to securably rotate as seen in US 2001/0045939A1, such that the electronic device can be operated in landscape or portrait mode. Where the stand is designed to function also as a handle, such rotation capability has the additional benefit of facilitating the device to be held and operated ergonomically at an angle preferred by the operator, or to be carried in the manner of a briefcase.

Such covers may alternatively consist only of a flap having a hinge for attachment to the electronic device. The front flap can offer both protection for the display and sometimes other benefits, for example, the front flap may be adapted to hold credit cards, or it may retain magnetic elements that interact with the electronic device for instance to activate the device upon opening the flap, or it may be segmented such that it can be folded up in a triangular structure elevating the display to a comfortable reading angle.

Other covers may consist of a combination of the aforementioned features for example a housing and a flap. However, in a cover possessing both a housing with a handle, and a flap, there is no obvious way to position the flap so as to permit access to the display when the device is being operated, yet still allowing the handle to be used. This problem is especially acute when the device is not resting on a surface but being carried. The problem is further complicated when the handle is rotatable.

Previous efforts at designing covers incorporating a flap have not addressed this problem. Conventional segmented flaps such as those described in U.S. Pat. No. 8,143,982 are designed to be folded up in a triangular formation, which suffers from the disadvantage that they include at least one protruding segment, whether partially or fully folded, preventing the segments from being folded flush one atop the other and the folded flap being positioned and releasably retained so as to allow ergonomic use of the handle.

There is thus a need to design a cover with a flap which can be folded compactly and stored about the cover so as to permit use of a stand or handle. It is an object of the present invention to provide a cover having a segmented flap which can be folded compactly and positioned conveniently when in its folded configuration.

### SUMMARY OF THE INVENTION

The present invention provides a foldable cover comprising a hinge suitable for attachment to a host unit, said host unit having a front face and a back face, and a flap portion pivotally connected to the hinge. The flap portion of the foldable cover comprises a plurality of segments with a foldable region between each of the segments. The flap portion is capable of being folded into a rectangular structure in which each of its segments is folded substantially flush one atop the other.

The size and arrangement of the segments permits the flap portion to be folded into a compact rectangular structure capable of being stored about the cover.

Preferably, each of the segments are substantially the same size and substantially rigid.

Preferably, each segment of the foldable cover includes a plurality of magnetic elements configured such that when one segment of the flap portion is folded atop its adjoining segment, forces of attraction between the magnetic elements releasably retain the two segments together.

Preferably, the rectangular structure so formed can be pivoted to the back face of the host unit and releasably retained in place on the back face by forces of attraction between magnetic elements in the host unit or the hinge and the overall magnetic field of the rectangular structure.

In an alternative embodiment, the rectangular structure can be pivoted to reside on the hinge and releasably retained in place on the hinge by forces of attraction between magnetic elements in the host unit or the hinge and the overall magnetic field of the rectangular structure.

In one embodiment, the host unit is itself an electronic device. In an alternative embodiment, the host unit is a case adapted for housing an electronic device, the case optionally including a handle on its back face. In this embodiment, the rectangular structure is preferably able to reside on the back face of the host unit without touching the handle.

For a better understanding of the invention and to show how the same may be performed, a preferred embodiment thereof will now be described, by way of non-limiting example only, with reference to the accompanying drawings.

### BRIEF DESCRIPTION OF THE DRAWINGS

Non-limiting examples are described with reference to the following figures, in which:

FIG. 1 shows a front view of a host unit having attached to it a foldable cover according to an embodiment of the invention, wherein the foldable cover is partially folded so as to cover the front face of the host unit.

FIG. 2 shows a side view of the cooperating system of FIG. 1.

FIG. 3 shows a side view of a foldable cover according to an embodiment of the invention, wherein the foldable cover is in a fully folded configuration and pivoted to reside on the back face of the host unit.

FIG. 4 shows a rear view of the cooperating system of FIG. 3.

FIG. 5 shows a partially cut-away plan view of a foldable cover according to an embodiment of the invention, wherein the foldable cover is in a fully unfolded position.

FIG. 6 shows a rear view of the cooperating system of FIG. 3, wherein the host unit further comprises a rotatable handle.

### DESCRIPTION OF PREFERRED EMBODIMENT

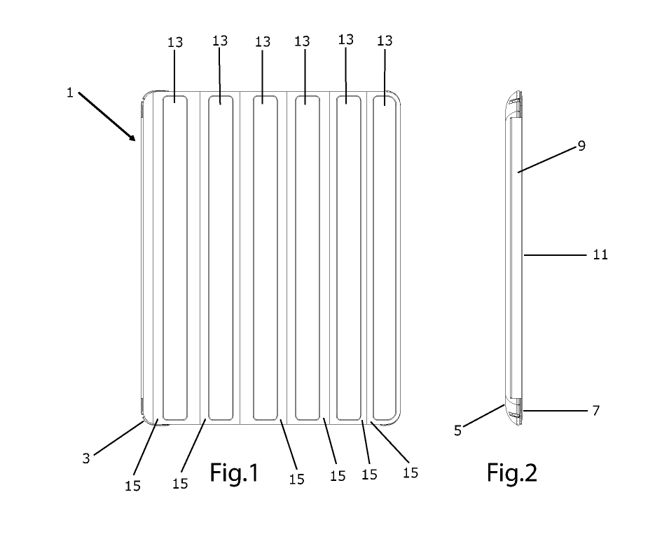

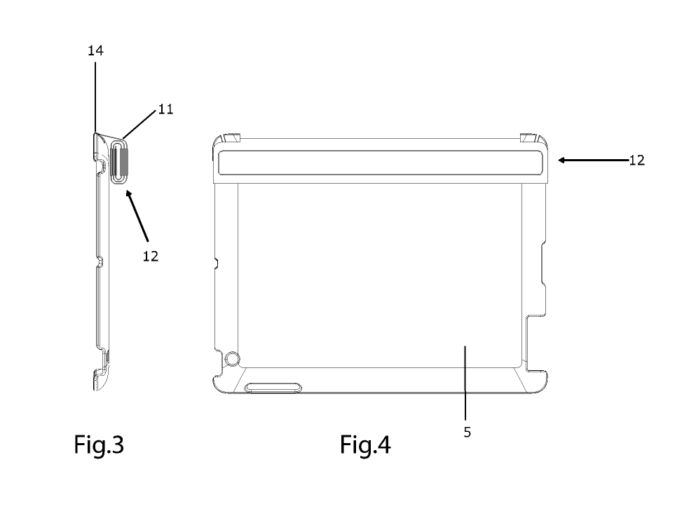

The following description relates in general to a foldable cover enhancing the protection of and facilitating the ergonomic operation of an electronic device. FIGS. 1 and 2 show a preferred embodiment of such a foldable cover according to the present invention.

The foldable cover 1 comprises a hinge 9 suitable for detachable attachment to a host unit 3 having a front face 7 and a back face 5. A flap portion 11 comprising a plurality of segments 13, with a foldable region 15 between each of the segments, is pivotally connected 14 to the hinge 9. In one embodiment, the hinge 9 and the flap portion 11 may be integrally formed, wherein the pivot 14 is provided by an edge of the host unit 3.

In one embodiment, the host unit 3 is an electronic device, for example a tablet computer, in which case the front face 7 of the host unit 3 is typically a display screen and/or input device. In a preferred embodiment, the host unit 3 is a case adapted for housing an electronic device, in which case the front face 7 of the host unit is typically a cavity into which the electronic device may be inserted.

In a preferred embodiment, the segments 13 are each of substantially the same size and substantially rigid. In between the segments 13 there are foldable regions 15 which are more flexible. The segmented design of the flap portion 11 permits the flap portion 11 to be folded into a compact rectangular structure 12 in which each of the segments 13 is folded substantially flush atop one another.

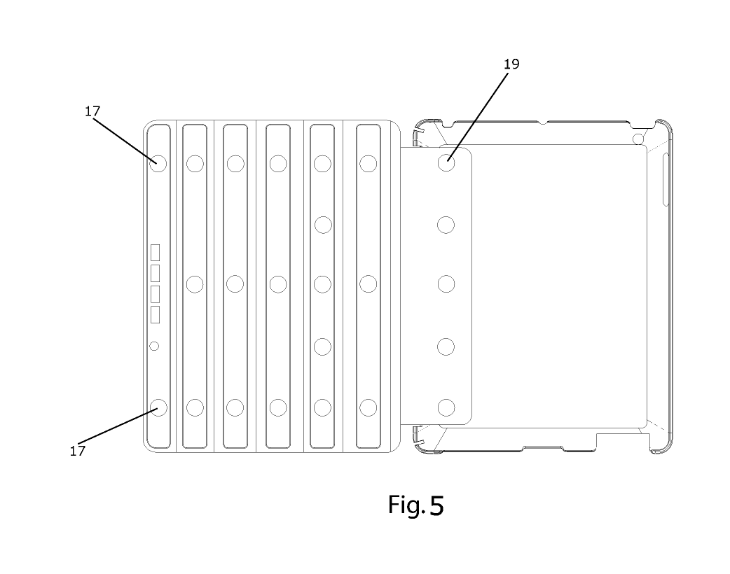

As can be seen in FIG. 5, in the preferred embodiment the segments 13 include magnetic elements 17. The magnetic elements 17 may be located either on the outside of the flap portion 11 or within the segments 13. The figure depicts a preferred configuration of magnetic elements 17 located within the segments 13. Forces of attraction between the magnetic elements 17 are capable of releasably attaching adjoining segments 13 together one atop the other when adjoining segments 13 are folded together. The arrangement of the magnetic elements 17 permits forces of magnetic attraction within and around the folded flap portion 11 to retain the flap portion 11 in a compact rectangular structure 12 until application of a releasing force stronger than the magnetic attraction overcomes the forces of magnetic attraction and releases the segments 13 from one another.

The pivot connection 14 enables the flap portion 11, whether in unfolded, fully folded or partially folded configuration, to pivot between the front face 7 of the host unit 3 and the back face 5 of the host unit 3. Preferably, the flap portion 11 is capable of residing at the front face 7 of the host unit 3 or the back face 5 of the host unit 3 when pivoted. In an alternative embodiment, the design and placement of the hinge 9 is such that the flap portion 11 is capable of residing either at the front face 7 of the host unit 3 or at the hinge when pivoted. In one embodiment the pivot connection 14 and the hinge 9 may be equivalent.

As shown in FIG. 5, in a preferred embodiment the host unit 3 includes magnetic elements 19. The magnetic elements 19 may be located either on the front face 7 or the back face 5 of the host unit 3, or preferably embedded within the host unit 3. In an alternative embodiment, the hinge 9 includes magnetic elements. In either case, the forces of attraction between the magnetic elements 19 in the back face 5 of the host unit 3, or those in the hinge 9, and the net magnetic force of the folded rectangular structure 12, are capable of releasably attaching the rectangular structure 12 to the back face 5 of the host unit 3 or to the hinge 9 as the case may be.

In a preferred embodiment, forces of attraction between the rectangular structure 12 and the magnetic elements 19 included in the host unit 3 magnetically attach the rectangular structure 12 to the back face 5 of the host unit 3 when the rectangular structure 12 is pivoted away from the the front face 7 of the host unit 3 to the back face 5 of the host unit 3. In an alternative embodiment, forces of attraction between the rectangular structure 12 and the magnetic elements 19 located in the hinge 9 magnetically attach the rectangular structure 12 to hinge 9 when the rectangular structure 12 is pivoted so as to reside on the hinge 9.

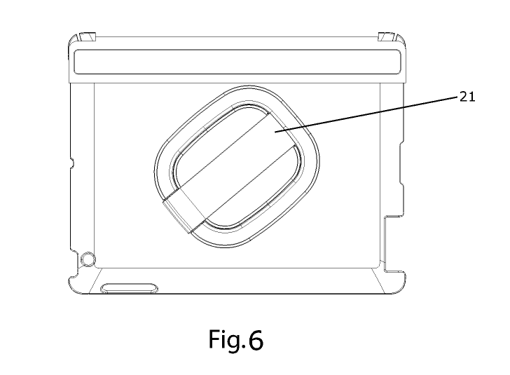

FIG. 6 shows a preferred embodiment of the invention in which the back face 5 of the host unit 3 includes a handle 21. The handle 21 facilitates the host unit to rest on a surface at a desired angle, and further facilitates the host unit to be held ergonomically. The handle 21 may be of a fixed type or it may be rotatable around a central axis perpendicular to the back face 5 of the host unit 3. The handle 21 may also be pivoted, such that the distance between a part of the handle and the back face 5 of the host unit 3 may be adjusted by an operator.

The compact nature of the rectangular structure 12 and the way it is held together magnetically, and the magnetic attachment of the rectangular structure 12 to the back face 5 of the host unit 3, permits the rectangular structure 12 to reside on the back face 5 of the host unit 3 or the hinge 9 without contacting the handle 21. Furthermore, in the preferred embodiment, the rectangular structure 12 is so compact and so well held together and in place that it permits the handle 21 to be ergonomically designed such that it may have an opening large enough to accommodate an operator's hand or wrist so that the host unit 3 does not need to be actively gripped by the operator, and such that the handle 21 is freely rotatable 360 degrees around its central axis.

The invention described herein is susceptible to variations, modifications and/or additions other than those specifically described and it is to be understood that the invention includes all such variations, modifications and/or additions which fall within the scope of the following claims.

1. A foldable cover, comprising:
a hinge suitable for detachable attachment to a host unit, said host unit having a front face and a back face; and
a flap portion pivotally connected to the hinge, the flap portion including a plurality of segments and a foldable region between each of the segments;
wherein the flap portion is capable of being folded into a rectangular structure in which each segment of the flap portion is folded substantially flush one atop the other.

2. The foldable cover according to claim 1, wherein the segments are substantially the same size and substantially rigid.

3. The foldable cover according to claim 2, wherein each segment includes at least one magnetic element.

4. The foldable cover according to claim 3, wherein the forces of attraction between the magnetic elements are capable of releasably attaching adjoining segments together.

5. The foldable cover according to claim 4, wherein the rectangular structure may be pivoted about the hinge.

6. The foldable cover according to claim 5, wherein the host unit includes at least one magnetic element.

7. The foldable cover according to claim 5, wherein the hinge includes at least one magnetic element.

8. The foldable cover according to claim 6, wherein the rectangular structure is capable of magnetic attachment to the back face of the host unit when pivoted to reside at the back face of the host unit.

9. The foldable cover according to claim 7, wherein the rectangular structure is capable of magnetic attachment to the hinge when pivoted to reside at the hinge.

10. The foldable cover according to claim 8, wherein the host unit is a case capable of housing an electronic device.

11. The foldable cover according to claim 9, wherein the host unit is an electronic device.

12. The foldable cover according to claim 10, wherein the back face of the host unit includes a handle.

13. The foldable cover according to claim 12, wherein the size of the rectangular structure permits the rectangular structure to reside on the back face of the host unit without touching the handle.

14. The foldable cover according to claim 12, wherein the handle is securably rotatable.

15. The foldable cover according to claim 10, wherein the electronic device is a tablet computer.

16. A foldable cover for an electronic device, comprising a case adapted to house the electronic device in a front cavity, a flap portion pivotally connected to the case by a hinge, the flap portion including a plurality of segments which are substantially the same size and substantially rigid and include at least one magnetic element, with a foldable portion between each segment, wherein the flap portion is capable of being folded into a rectangular structure in which each of its segments is folded substantially flush one atop the other and releasably held together by forces of attraction between their magnetic elements, and in that the rectangular structure may be pivoted to reside at the rear of the front cavity and releasably held there by forces of magnetic attraction between the rectangular structure and magnetic elements included in the case.

17. The foldable cover according to claim 16 wherein the case further includes a rotatable handle.
